(19) United States
(12) Patent Application Publication
(10) Pub. No.: US 2014/0227889 A1
(43) Pub. Date: Aug. 14, 2014

(54) LASER-BASED MATERIALS PROCESSING APPARATUS, METHOD AND APPLICATIONS

(71) Applicant: University of Central Florida Research Foundation, Inc., Orlando, FL (US)

(72) Inventors: Lawrence Shah, Maitland, FL (US); Martin C. Richardson, Geneva, FL (US); Ilya Mingareev, Winter Park, FL (US); Mark Ramme, Orlando, FL (US); Tobias Bonhoff, Aachen (DE); Pankaj Kadwani, Orlando, FL (US)

(73) Assignee: University of Central Florida Research Foundation, Inc., Orlando, FL (US)

(21) Appl. No.: 14/179,107

(22) Filed: Feb. 12, 2014

Related U.S. Application Data
(60) Provisional application No. 61/764,277, filed on Feb. 13, 2013.
(60) Provisional application No. 61/764,705, filed on Feb. 14, 2013.

(51) Int. Cl. H01L 21/268; B23K 26/36; B23K 26/00

(52) U.S. Cl. CPC H01L 21/268; B23K 26/0066; B23K 26/36
USPC 438/795; 219/121.73; 219/121.72

(57) ABSTRACT

In a particular embodiment, a relatively high-energy thulium fiber laser operating at the wavelength λ=2 μm may be used to selectively modify a front and/or a back surface of silicon and gallium arsenide wafers. The processing regime was studied in terms of the process parameters variation, and the corresponding modification fluence thresholds were determined. The results revealed considerable differences in morphology between front and back surface modifications, and that the back surface modification threshold of Si is significantly higher than at the front surface. Basic analytic modeling and z-scan measurements were performed to study the absorption mechanisms. In a broader embodiment the processing regime is not specifically limited to a thulium fiber laser.

### CROSS-REFERENCE TO RELATED APPLICATION

This application is related to, and derives priority from: (1) U.S. Provisional Patent Application Ser. No. 61/764,277, filed 13 Feb. 2013; and (2) U.S. Provisional Patent Application Ser. No. 61/764,705, filed 14 Feb. 2013, each of the foregoing provisional patent applications being titled Fiber Laser Apparatus, Materials Processing Method, and Application, the content of which is incorporated herein fully by reference.

### STATEMENT OF GOVERNMENT INTEREST

The research that lead to the embodiments as disclosed herein, and the invention as claimed herein, was funded by: (1) the United States Joint Technology Office multidisciplinary research initiative (under contract #FA9550-10-1-0543); and (2) the United States Office of Naval Research (under contract #N000141210144). The United States government has rights in any patent that results from the invention as claimed herein.

### BACKGROUND

1. Field of the Invention

Embodiments relate generally to materials processing apparatus, methods and applications. More particularly embodiments relate to advanced laser-based materials processing apparatus, methods and applications.

2. Description of the Related Art

The study of a pulsed laser/material substrate interaction and applications of the resulting pulsed laser treated material substrate has been a subject of immense academic and practical interest for at least the last two decades. In that regard, various pulsed laser/material substrate processing regimes have been extensively studied. Since pulsed laser apparatus within the context of materials processing is likely to continue to expand in context with the scope of applications, desirable are additional advances in pulsed laser apparatus within the context of materials processing applications.

### SUMMARY

The embodiments describe and derive from experimental studies on pulsed laser processing of silicon semiconductor substrate wafers and gallium arsenide semiconductor substrate wafers with nanosecond laser pulses produced by a thulium-doped photonic crystal fiber (Tm:PCF) master oscillator power amplifier (MOPA) laser apparatus system operating at the wavelength λ=2.0 μm (photon energy (Eₚₕ)≈0.62 eV). Pulsed Tm:PCF laser systems may be known in other applications that require relatively high peak power pulses and nearly diffraction-limited beam quality with linear polarization. Therefore, in particular applications it is highly advantageous to use fiber laser apparatus that offer the largest possible mode area while maintaining fundamental mode propagation. To that end, it has been demonstrated that thulium-doped photonic crystal fibers (PCF) may provide mode areas>1000 μm² and yield nearly perfect beam quality and polarization, and that these fibers are well suited for use in high peak power Q-switched oscillators. Within the context of recorded demonstrations to date, PCFs have been used to scale peak powers towards the MW level in thulium-based MOPA systems.

By taking advantage of a silicon or gallium arsenide semiconductor substrate material transparency at λ=2 μm, modifications can be induced not only at the front (laser incident) surface of a semiconductor substrate wafer, but also at the back surface of a relatively thin semiconductor substrate wafer. One may experimentally confirm that the back surface of Si and GaAs semiconductor substrate wafers can be modified independently, without inducing damage to the front surface. As described in greater detail within the Detailed Description of the Non-Limiting Embodiments, the influence of process conditions on the resulting surface morphology change may be studied by varying at least one of an incident laser pulse energy (i.e., Eₚ), a wafer translation speed and a laser pulse duration time (i.e., tₚ). Such laser-induced surface modification of a semiconductor substrate wafer may be investigated by optical microscopy and scanning electron microscopy (SEM), and the modification thresholds for multiple-pulse irradiation may be estimated for semiconductor substrate wafer front surfaces and semiconductor substrate wafer back surfaces. In addition, basic z-scan transmission measurements may be performed to evaluate the contribution of multi-photon absorption (MPA) mechanisms to processing of semiconductor substrate wafers at the wavelength λ=2 μm.

In addition to the incident laser pulse energy, the wafer translational speed and the laser pulse duration as designated above, in general the embodiments also require that a photon energy of a materials processing apparatus or a materials processing method in accordance with the embodiments is less than a bandgap energy of a material that comprises a material substrate that is intended to be processed using the materials processing apparatus and the materials processing method. Thus a multi-photon apparatus and a multi-photon method is contemplated in accordance with the embodiments. The multi-photon apparatus and the multi-photon method contemplate at least 2 photons and potentially more, such as but not limited to at least about 4 photons.

The embodiments may be claimed within the context of at least one of a materials processing apparatus and a related materials processing method.

A particular material processing apparatus in accordance with the embodiments includes a pulsed laser component having an output beam characterized by a pulse energy from about 1 nJ to about 2 mJ, a pulse time from about 50 ps to about 500 ns and a photon energy less than a bandgap energy of a material substrate intended to be processed using the materials processing apparatus. The particular material processing apparatus in accordance with the embodiments also includes a computer controlled platen component suitable for positioning the output beam with respect to the planar dimensions of the material substrate located upon a platen that comprises the computer controlled platen component. The particular material processing apparatus also includes an optical focusing component suitable for focusing the output beam through a depth of the material substrate located upon the platen.

A particular material processing method in accordance with the embodiments includes treating a material substrate with an output beam of a pulsed laser characterized by a pulse energy from about 1 nJ to about 2 mJ, a pulse time from about 50 ps to about 500 ns and a photon energy less than a bandgap energy of a material that comprises the material substrate, to provide a processed material substrate.

Another particular material processing method in accordance with the embodiments includes irradiating a front side of a semiconductor substrate with an output beam of a thulium fiber pulsed laser characterized by a pulse energy from about 1 nJ to about 2 mJ, a pulse time from about 50 ps to about 500 ns and a photon energy less than a bandgap energy of a semiconductor material that comprises the semiconductor substrate, to provide a processed semiconductor substrate processed on a backside of the processed semiconductor substrate while not damaging the front side of the processed semiconductor substrate.

### BRIEF DESCRIPTION OF THE DRAWINGS

The objects, features and advantages of the embodiments are understood within the context of the Detailed Description of the Non-Limiting Embodiments, as set forth below. The Detailed Description of the Non-Limiting Embodiments is understood within the context of the accompanying drawings, that form a material part of this disclosure, wherein:

FIG. 1 shows: (a) a beam profile of a MOPA system in accordance with the embodiments; and (b) a schematic diagram of an experimental configuration of the MOPA system in accordance with the embodiments.

FIG. 2 shows s plurality of SEM images of front surface craters produced in Si and GaAs while using a MOPA system in accordance with the embodiments for 1000 pulses at Eₚ=120 μJ.

FIG. 3 shows a pair of SEM images of front surface trenches produced in Si and GaAs at Eₚ=120 μJ, tₚ=7 ns and v=1 mm/s.

FIG. 4 shows a pair of SEM images of back surface trenches produced in Si and GaAs at tₚ=7 ns, v=1 mm/s. Left: Si processed at Eₚ=320 μJ. Right: GaAs processed at Eₚ=120 μJ.

FIG. 5 shows results of an open-aperture z-scan measurement. Negative z values represent a laser focus being below a wafer surface.

FIG. 6 shows a schematic diagram of a laser welding apparatus in accordance with the embodiments.

### DETAILED DESCRIPTION OF THE NON-LIMITING EMBODIMENTS

The embodiments provide a laser apparatus for processing a material substrate, such as but not limited to a semiconductor substrate wafer, and a method for processing the material substrate, such as but not limited to the semiconductor substrate wafer. The apparatus and the method in accordance with the embodiments are predicated upon use of a pulsed laser having a particular pulse energy, pulse time and photon energy. The processing of the material substrate provides at least one of a front side and a back side modification of the material substrate.

### 1. GENERAL CONDITIONS FOR MATERIALS PROCESSING IN ACCORDANCE WITH THE EMBODIMENTS

In accordance with a specific embodiment, the embodiments provide for use of a thulium doped photonic crystal fiber (Tm:PCF) laser lasing at about 2 μm for purposes of processing either one or both of a front side and a back side of a semiconductor substrate wafer. More generally, however, the embodiments are not intended to be so limited. Rather the embodiments are intended to be operative when using any type of pulsed laser system for modifying materials substrate, and more particularly a semiconductor substrate wafer including but not limited to a silicon semiconductor substrate wafer and a gallium arsenide semiconductor substrate wafer at: (1) a pulse energy from about 1 nJ to about 2 mJ (or alternatively about 100 nJ to about 100 μJ); (2) a pulse time from about 50 ps to about 500 ns (or alternatively about 250 ps to about 100 ns); and (3) a photon energy less than a bandgap energy of a material substrate intended to be processed using the materials processing apparatus.

The embodiments also consider when forming a trench within material substrate a substrate vs laser beam relative traveling velocity from about 0.1 mm/sec to about 100 m/sec, although higher relative travelling velocities in the range of hundreds of m/sec are possible presuming an adequately powerful laser.

In general, a material substrate processed in accordance with the embodiments may be selected from the group including but not limited to conductor material substrates, semiconductor material substrates and dielectric material substrates (i.e., which may all be accessible within the context of heavily doped, lightly doped and undoped semiconductor substrate materials). Typically and preferably, the material substrate processed in accordance with the embodiments will have a thickness from about 50 μm to about 10 mm, and preferably from about 100 to about 1000 μm.

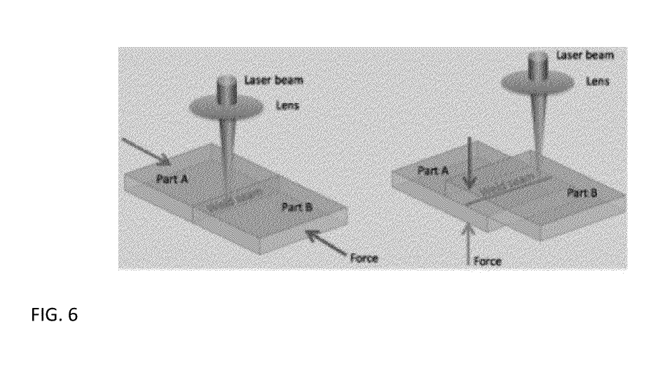

Beyond the possibility of modifying a semiconductor substrate wafer by forming: (1) a crater aperture within a front side of the semiconductor substrate wafer; (2) a trench aperture within a front side of the semiconductor substrate wafer; or (3) a trench aperture within a backside of the semiconductor substrate wafer, the embodiments also contemplate other materials processing applications that may be effected in accordance with the embodiments while using similar materials systems in accordance with the embodiments. Such other materials processing applications may include, but are not necessarily limited to: (1) materials substrate dicing applications; (2) materials substrate metallization removal applications; (3) materials substrate surface alloying (i.e.,spatially selective surface doping) applications; (4) materials substrate layer connection (i.e., such as but not limited to welding) applications; and (5) materials substrate layer disconnection applications. A particular apparatus for laser welding material substrate layer connection applications is illustrated in FIG. 6. Related apparatus for the remaining of the above applications are also readily considered by a person of ordinary skill in the art.

### 2. SPECIFIC EMBODIMENT

2.1 Specific Conditions for Materials Processing in Accordance with a Specific Embodiment

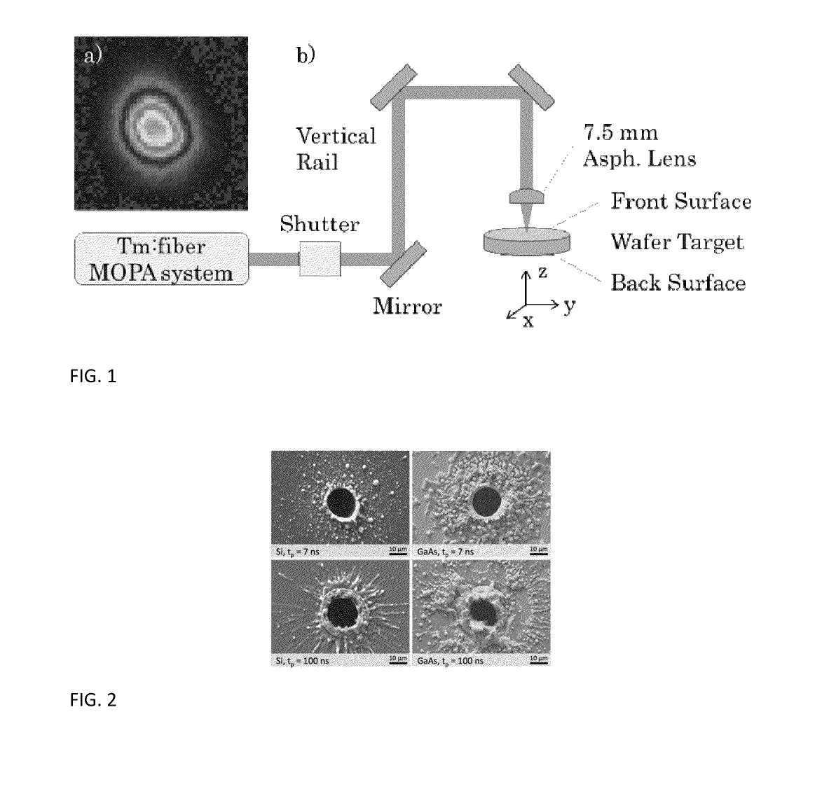

For a semiconductor substrate wafer pulse irradiation experiment, a first amplifier stage of a MOPA system in accordance with FIG. 1b was used. Additional details of the MOPA system are described in Gaida et al., “Amplification of nanosecond pulses to megawatt peak power levels in Tm3+-doped photonic crystal fiber rod,” Optics Letters 38 (69) (2013). The maximum peak power was >40 kW, with 400 μJ maximum pulse energy (immediately before a focusing lens) at pulse duration 6.8 ns and 1 kHz repetition rate. The output was linearly polarized, the beam diameter was approx. 4.5 mm (immediately before the focusing lens), and the spectral width was <1 nm (FWHM) at the wavelength 1985 nm. The pulse duration was adjustable in the range tₚ=6.8-100 ns. FIG. 1a shows the beam profile (immediately before the focusing lens) of the MOPA system.

Intrinsic, double-side polished semiconductor wafers were used in the experiments. The Si wafers (Cz-Si, Virginia Semiconductor) had a thickness of 500 μm with the normal axis along a

crystal direction, and the GaAs wafers (Wafer World) were 600 μm thick with the normal axis along a [100] crystal direction. As shown in FIG. 1b, the output of the MOPA system was directed through a mechanical shutter (Uniblitz) in order to control the number of pulses incident on the target semiconductor substrate wafer. The beam was then directed along a vertical rail to achieve normal incidence of the beam onto the horizontally mounted targets. The beam was focused to a sub-10 μm spot size using an aspheric lens with a focal length f=7.5 mm. The wafer targets were mounted on a computer controlled 3-axis motion controller stage (Newport VP-25X), while the lens was stationary.

The repetition rate was set to fᵣₑₚ=1 kHz for all surface modification experiments. Irradiations were performed at pulse energies Eₚ<350 μJ (directly out of a laser system), and at two pulse durations tₚ=7 ns and tₚ=100 ns. Trenches were produced by translating the sample in the focal x-y plane at a constant speed orthogonally to the incident laser beam. Alternatively, irradiation with a specified number of laser pulses carried out at fixed positions produced surface craters. Surface modifications were analyzed by optical microscopy (Olympus BX51) and scanning electron microscopy (JEOL JSM-6480). Energy-dispersive x-ray spectroscopy (EDX) was utilized to investigate the elemental composition of the laser-produced debris. Processed samples were not cleaned before surface characterization in order to examine the morphology, amount, and composition of process-induced debris.

2.2 Surface Morphology Changes

Experimental conditions and the resulting surface morphology modifications were investigated both for the front and the back processing of the sample semiconductor substrate wafer surfaces. In a first series of experiments, the laser radiation was focused on the front surface of the samples (z₀ position) to study the resulting morphology change by translating the sample and at fixed points, in dependence on the laser pulse energy and the pulse duration.

The morphology of craters produced in Si and GaAs with 1000 pulses at 7 and 100 ns pulse duration revealed differences in material response to laser irradiation, as illustrated in FIG. 2. Depending on the pulse duration, as the material undergoes melting and sublimation, its products are ejected and re-solidified at the surface differently. In case of Si, the material removal process was accompanied with the dispersion of micrometer-sized, mostly spherically shaped debris particles to a wide surface area for tₚ=7 ns. For tₚ=100 ns pulses, the area surrounding the craters was covered with up to ≈60 μm long, radially distributed re-solidified material “splatter” originating from the craters. Ring-like surface swellings were observed around the craters, probably resulting from the periodical melting and re-solidification process, and indicating a larger contribution of thermal phenomena during irradiation with longer laser pulses. When the same experimental conditions were applied for processing of GaAs samples, a larger amount of debris was generated compared to Si. A large round area around the craters was splash coated with ablation products. EDX measurements indicated up to 18 wt % of oxygen in close vicinity (≈10 μm) of craters, with the oxygen fraction vanishing with increasing distance from the craters. The debris film appeared cracked, and also exposed sites where the debris stripped off the wafer surface. These sites did not seem to be significantly heat-affected, showing extremely smooth surface quality and approx. 0.5 wt % of oxygen according to the EDX analysis similar to the unprocessed bulk material. Irradiation of GaAs with tₚ=100 ns pulses produced an excessive amount of recast material.

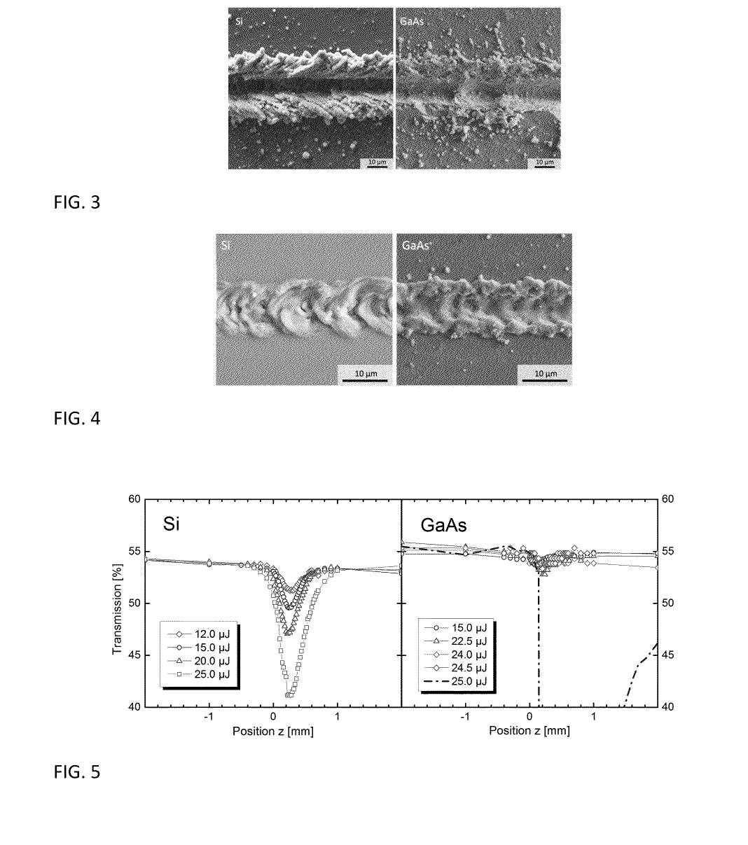

Trenches were produced on the front surface of Si and GaAs samples by applying the same experimental conditions as for the irradiation at fixed positions, and by translating the samples in the x-y plane at a constant speed v=1 mm/s resulting in a spatial pulse overlap of approx. 90%. The trenches obtained in Si, as shown in FIG. 3, at left, were surrounded by a large amount of melted and re-solidified material and individual micrometer-sized melt droplets dispersed on the surface. Similar to irradiation at fixed surface positions, processing of trenches in GaAs, as shown in FIG. 3, at right produced a continuous debris film as well as sporadic splashes of re-solidified material.

In a second series of experiments, transparency of semiconductors at the wavelength λ=2 μm was utilized to induce surface modifications at the back surface. When a focused laser beam passes through a Si or a GaAs wafer (refractive indices n_{Si}=3.45 and n_{GaAs}=3.36 for λ=2 μm), it is subject to considerable refraction and Fresnel reflections from both surfaces. In general, these effects can significantly affect focusing conditions at the back surface due to spherical aberrations and multiple reflections of the beam inside the wafer. In addition, semiconductors exposed to high-intensity electromagnetic fields can be considerably altered giving rise to nonlinear optical effects, such as absorption, beam focusing/defocusing and scattering. Therefore irradiation conditions at the back surface cannot be compared to front surface irradiation directly. Sequential ray-tracing modeling using Zemax was carried out to simulate the intensity distribution and the focus position at the back surface by taking into account linear refraction and aberrations effects.

To achieve back surface modifications the wafer was first translated approximately Δz=1 mm along the z-axis towards the focusing lens. This procedure ensured the initial laser focus was well below the back surface of the wafer. Afterwards the distance between the assumed focus position and the back surface was gradually reduced while concurrently translating the wafer in the x-y plane at 1 mm/s to produce trenches. Irradiations were performed at different pulse energies to determine the threshold value for the processing initiation. The onset of the back surface modification in GaAs as illustrated in FIG. 4, right hand side was observed at a position offset Δz≈210±20 μm measured from the initial z₀ position, which roughly corresponds to the focus being at the back surface according to simulation data for a 600 μm thick wafer. The modification morphology revealed trenches apparently induced by a thermal melting process, predominantly. Compared to modifications achieved at the front surface, the areas surrounding the trenches were covered with a notably reduced amount of debris. Remarkably, at pulse energies adopted, surface analysis by optical microscopy and SEM indicated no evidence of modification at the corresponding sites of the front surface in GaAs.

Back surface irradiation of Si, as illustrated in FIG. 4, was carried out utilizing the same procedure as for GaAs. Following the same geometric considerations and taking into account possible spherical aberrations and the optical path length in a 500 μm thick Si wafer, the wafer position offset corresponding to the beam focus being at the back surface was estimated to Δz≈180±20 μm using the ray-tracing model. However in the experiment, processing of Si at pulse energies comparable to those adopted for GaAs, did not result in any detectable back surface modification, and only the front surface could be modified as Δz decreased to zero. By repeating the experiment while gradually increasing the pulse energy, the onset of the back surface modification was observed at a much larger offset of Δz≈450 μm than predicted by simulations. The resulting surface morphology represented trenches produced presumably by local surface re-melting process, however no evidence of debris generation was detected. Similar to GaAs, no visible damage was induced to the front surface of Si at these experimental conditions.

2.3 Determination of Modification Thresholds

To determine the energy density thresholds for the front surface modifications, surface craters were produced by applying 20 pulses at varying pulse energies Eₚ=10-150 μJ. After irradiation the diameters d of the craters were determined by optical microscopy. Using this experimental data and the model from Liu et al., Optics Letters, Vol. 7 (5), p. 196, May 1982, determination of crater threshold as a function of incident energy may be undertaken.

More specifically, the threshold determination model is based on performing single spot irradiations of a substrate surface at different energies (using near-Gaussian beams), and determination of the outer diameters from obtained circular craters. Semilog plots of the energy dependence of the outer radii/diameters will result in linear dependencies of d² versus ln E according to equation (1). Thus a linear regression can determine the values for the minimum modification crater diameter and the minimum/threshold energy Eth (or fluence Fth) necessary to induce modification.

d²=2w₀² ln(E/Eₜₕ)=2w₀² ln(F/Fₜₕ), (1)

As indicated above, the beam waist size w₀, and the modification fluence threshold Fₜₕ can be determined by performing a linear regression of d² as a function of ln E. Evaluation of the experimental data resulted in the beam waist w₀=10 μm in all measurements performed at the front surface. The fluence threshold data for the pulse durations 7 and 100 ns is summarized in Table 1.

TABLE 1
Front and back surface modification thresholds for
Si and GaAs at λ = 2 μm.

| | | Front surface | Back surface |
|---|---|---|---|
| | | fluence | fluence |
| | Pulse duration | threshold^{a} | threshold^{b} |
| Material | [ns] | [J/cm²] | [J/cm²] |
| Si | 7 | 2.86 | <17.2 |
| | 100 | 3.22 | |
| GaAs | 7 | 2.30 | <3.2 |
| | 100 | 3.38 | |

^{a}Determined for craters produced with 20 pulses
^{b}Estimated for trenches with 10 effectively incident pulses

Irradiations performed with a smaller number of pulses did not deliver consistent results, which was caused by considerable discrepancies in the crater diameters obtained. However, one may confirm experimentally that the fluence threshold values were in general larger with the smaller numbers of pulses (<20) applied. Similar dependency has previously been reported for nanosecond laser processing of semiconductors at other wavelengths. See, e.g., Wang et al., J. Applied Physics 108, 033103 (2010) and Qi et al., Optics and Lasers in Engineering 49, 285-291 (2011).

A reliable determination of the back surface modification thresholds was not possible by measuring the crater diameters due to mainly probabilistic nature of their generation and large discrepancies in their diameters. Experiments showed that only wafer processing by translating the samples in the x-y plane resulted in consistent modifications induced at the back surface. In addition, while performing such experiments, one may observe modifications being occasionally initiated by laser beam interaction with microscopic irregularities of the wafer surface, e.g., micro-craters and scratches. This initiation effect implies damage accumulation phenomena play an important role in the physical mechanism of back surface processing. Therefore based on the experimental results obtained one can only provide an upper limit estimation of the modification thresholds.

The minimum pulse energy necessary to induce back surface trenches in GaAs was Eₚ=18 μJ. Without an exact knowledge of light propagation and absorption conditions in the bulk it was impossible to determine what fraction of the incident optical energy was effectively contributing to the back surface modification process. Thus the only measurable parameter was the transmittance T_{GaAS}=54.6% through the entire wafer. Assuming the laser beam waist of w₀=10 μm as resulted from ray-tracing modeling, taking into account the wafer transmittance, and considering the accumulated energy applied to a single spot being equivalent to 10 pulses, the corresponding fluence threshold was estimated to Fₜₕ<3.2 J/cm² for 10 pulses at tₚ=7 ns.

For Si, the minimum pulse energy required for consistent back surface modification was Eₚ≈100 μJ, however sporadic modifications were also possible at lower pulse energies. With the total wafer transmittance T_{Si}=53.4% and the offset Δz corresponding to the processing initiation being much larger than predicted by ray tracing modeling, only a rough estimation for the modification threshold can be given. Accordingly, the back surface modification threshold for Si is Fₜₕ<17.2 J/cm² for 10 pulses with the pulse duration tₚ=7 ns.

### 3. DISCUSSION

For a conclusive evaluation of the experimental results obtained at the wavelength 2 μm, it is essential to review the underlying physical mechanisms responsible for semiconductor processing. In particular, similarities and differences to processing in the non-transparent regime, i.e., with photon energies hv>E_{g} need to be highlighted. On the one hand, the front surface modification thresholds for Si and GaAs were similar to the values obtained for processing at shorter wavelengths. For example, Fₜₕᵣ=4.8 J/cm² was reported for single pulse irradiation with 20 ns pulses at λ=1.064 μm. Values in the range Fₜₕᵣ=2.5-3.8 J/cm² were reported for differently doped Si. A wide range of threshold values Fₜₕᵣ=0.5-3.8 J/cm² was reported for GaAs irradiated with nanosecond pulses at different wavelengths. On the other hand, the materials under investigations were pure, which allowed a spatially selective processing of the wafers' back surfaces. This implies significant differences in the underlying modification mechanisms and principles.

In general, laser-semiconductor interaction utilizing high-intensity laser pulses with photon energies Eₚₕ>E_{g} reveals three primary absorption mechanisms. First, intrinsic absorption is caused by interband electronic transitions. Free carrier absorption is the second important mechanism that involves photo-induced intraband transitions followed by the energy transfer to the lattice. The third absorption mechanism, which is characteristic for impure and contaminated materials, is initiated by defects and impurities leading to a lowered energy band gap. Multi-photon absorption is usually not considered an important absorption mechanism for semiconductor processing with Eₚₕ>E_{g}, because material modifications such as melting and ablation occur at much lower intensities than needed for multi-photon absorption to become predominant.

In contrast, for photon energies Eₚₕ<E_{g} and pure semiconductors, intrinsic absorption vanishes, and free-carrier absorption becomes negligible. Therefore the effects of multi-photon absorption on material processing require further considerations involving energy budget analysis for different experimental conditions. In addition, electron avalanche ionization is an important, secondary nonlinear carrier excitation mechanism that however requires background (seed) electrons generated by aforementioned absorption processes. Therefore knowledge of the origin and the density of photo-excited seed electrons is essential for the evaluation of the material modification processes for different photon energies.

Following a simple, first-principles model describing laser heating of semiconductor surfaces and their thermomechanical behavior, the temperature rise of a material irradiated at a fluence F can be estimated. See, e.g., Meyer et al., Phys. Rev. B vol 21 (4), p 1559 (1980). If the optical energy is added to the material uniformly within the heating depth L_{H}, the temperature rise ΔT can be expressed as:

$$Δ T = \frac{F ( 1 - R )}{ρ {cL}_{H}} , \qquad ( 2 )$$

where R is the reflectivity, c is the specific heat of the material and ρ is the mass density. In general, the heating depth L_{H} can be expressed by the following approximation:

$${L}_{H} \approx \frac{1}{α} + {L}_{D} + {L}_{T} , \qquad ( 3 )$$

where L_{D} is the carrier diffusion length, and L_{T} is the thermal diffusion length. The total absorption coefficient a can be expressed as a sum of α_{SP}, α_{MP} and α_{FC} representing single-photon, multi-photon, and free-carrier absorption coefficients, respectively. At λ=2 μm, intrinsic absorption is not present and the free carrier absorption is negligible, α_{FC}<<1 cm⁻¹ for materials under investigation. Accordingly, multi-photon absorption is considered the only primary absorption process supplying seed electrons for avalanche ionization and subsequent lattice heating. L_{D} is dependent on the carrier lifetime and the material temperature, and considered to be on the order of 1 μm or smaller for Si and GaAs irradiated with nanosecond pulses. For 7 ns pulses, the thermal diffusion depth L_{T}˜tₚ^{1/2} is negligibly small as well. Therefore, assuming no other primary photoionization processes are involved in semiconductor laser processing at λ=2 μm, equation (3) can be simplified to L_{H}≈α⁻¹≈α_{MP}⁻¹.

In the experiments described herein, the multi-photon absorption phenomena possibly involved in laser-semiconductor interaction are the two-photon absorption in Si with the 2PA coefficient β_{Si}≈0.25 cm/GW], and the three-photon absorption in GaAs with the 3PA coefficient γ_{GaAs}≈0.18 cm³/GW². By calculating α_{MP} for both materials, and using the experimentally obtained modification threshold values (Table 1) in equation (2), the corresponding temperature rise induced by a single laser pulse would be on the order of only 1 K. In fact, in order to increase the surface temperature to the melting point, a total absorption coefficient on the order of α˜10³-10⁴ cm⁻¹ would be required. Therefore, the contribution of the multi-photon absorption processes to the material modification is very small, but not negligible as it can still provide seed electrons for avalanche ionization.

In order to evaluate these generalized considerations qualitatively, basic open-aperture z-scan measurements were performed with Si and GaAs wafers. The z-scan technique allows studying nonlinear optical properties of transparent materials. A triplet lens (f=25 mm) was used for beam focusing. The repetition was set to fᵣₑₚ=10 kHz rate, and the pulse duration was set to tₚ=100 ns, to reduce the risks of wafer damage and to provide sufficient laser power for reliable measurements. Transmission through the wafers was determined as a function of the position z and the pulse energy Eₚ. Measurements were repeated 5 times, and the wafers were translated in the x-y plane before each new measurement to avoid possible interferences from previous exposures. The results of the z-scan measurements, as illustrated in FIG. 5, revealed a transmission drop for both materials as the focused beam passed through the wafer. In Si, the transmission decreased from 53.4% to approx. 41% for Eₚ≦25 μJ, and this dependency was in general nonlinear. In GaAs, the transmission decrease was only about 1-2%, being nearly constant for pulse energies in the range Eₚ≦24.5 μJ. However at Eₚ≧25 μJ a dramatic decrease in transmission was observed, presumably indicating the initiation of wafer modification processes.

From the results of the z-scan measurements, it can be concluded that two-photon absorption can play a significant role in the modification mechanism of Si, whereas three-photon absorption in GaAs does not appear to contribute to the material modification significantly. Therefore an alternative absorption mechanism responsible for the generation of a sufficient seed electron density must be assumed.

A reasonable physical model for the alternative surface-enhanced absorption mechanism has recently been proposed. See, e.g., Iwata et al., Japanese J. of Appl. Physics vol 47 (4), pp. 2161-2167 (2008). According to this model, the existence of a very thin absorbing layer located at the surface of the wafer can be considered. Very thin layers cannot be detected by conventional absorption measurement techniques. Microscopic and nanoscopic sites featuring dangling bonds, native oxide layers and various lattice defects can initiate the absorption process within the layer. These sites can absorb light with the photon energy below the band gap. This model is supported by our experimental observations of the surface modification morphology. Isolated random micro-damage zones are present in both materials in the focal region, when the laser intensity is close to the threshold. With the increasing number of laser pulses applied these zones occupy larger surface areas. Therefore accumulation of laser-induced microscopic defects is one of the driving mechanisms leading to surface modifications observed in the experiments. Light absorption is considerably enhanced by these defects, which provides additional charge carriers for the subsequent avalanche ionization and thermal modification processes.

In addition, it should be noted that absorption of Si and GaAs irradiated at λ=2 μm can be considerably affected by the material temperature. In general, the energy band gap of semiconductors decreases with the increasing temperature. This effect can give rise to more favorable conditions for absorption at defect sites. Moreover, when the temperature of GaAs reaches approx. 420° C., the decreased E_{g} makes two-photon absorption possible. However the 2PA coefficient is generally small at the corresponding energy threshold, and thus the contribution of the two-photon absorption in GaAs can be considered unimportant in our experiments. Further experimental investigations and modeling are needed to develop a thorough understanding of the underlying fundamental mechanisms resulting in trans-wafer processing of semiconductors, as well as the effects of the process parameters on the processing results.

### 4. CONCLUSION

In summary, surface modifications in Si and GaAs irradiated with nanosecond pulsed laser radiation at the wavelength 2 μm were studied. Modifications were induced both at the laser-incident, front surface and at the back surface. Characterization by optical microscopy and SEM showed that morphology changes were caused mainly by thermal melting and re-solidification phenomena resulting in a different amount of debris produced at the surface. Consistent modification of the back surfaces was only possible when processing in surface trenches, as opposed to irradiation at fixed positions. Modification thresholds were determined for both materials at the front surface, at pulse durations of 7 and 100 ns. Effective modification thresholds were estimated for the back surface irradiation. Basic analytic models of the laser-induced semiconductor heating were adopted to investigate the absorption conditions at the wavelength 2 μm, and to estimate the role of multi-photon absorption in modification processes. Intensity-dependent transmission measurements (z-scans) reveal a possible contribution of two-photon absorption to modification.

All references, including publications, patent applications, and patents cited herein are hereby incorporated by reference in their entireties to the extent allowed, and as if each reference was individually and specifically indicated to be incorporated by reference and was set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

The recitation of ranges of values herein is merely intended to serve as a shorthand method of referring individually to each separate value falling within the range, unless otherwise indicated herein, and each separate value is incorporated into the specification as if it was individually recited herein.

All methods described herein may be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

What is claimed is:

1. A materials processing apparatus comprising:
a pulsed laser component having an output beam characterized by a pulse energy from about 1 nJ to about 2 mJ, a pulse time from about 50 ps to about 500 ns and a photon energy less than a bandgap energy of a material substrate intended to be processed using the materials processing apparatus;
a computer controlled platen component suitable for positioning the output beam with respect to the planar dimensions of the material substrate located upon a platen that comprises the computer controlled platen component; and
an optical focusing component suitable for focusing the output beam through a depth of the material substrate located upon the platen.

2. The apparatus of claim 1 wherein the pulsed laser component comprises a thulium fiber laser.

3. The apparatus of claim 1 wherein the material substrate comprises a substrate material selected from the group consisting of conductor substrate materials, semiconductor substrate materials and dielectric substrate materials.

4. The apparatus of claim 1 wherein the material substrate comprises a silicon semiconductor substrate material.

5. The apparatus of claim 1 wherein the material substrate comprises a gallium arsenide semiconductor substrate material.

6. The apparatus of claim 1 wherein the apparatus comprises a materials substrate dicing apparatus.

7. The apparatus of claim 1 wherein the apparatus comprises a materials substrate metallization removal apparatus.

8. The apparatus of claim 1 wherein the apparatus comprises a materials substrate surface alloying apparatus.

9. The apparatus of claim 1 wherein the apparatus comprises a materials substrate layer connection apparatus.

10. The apparatus of claim 1 wherein the apparatus comprises a materials substrate layer disconnection apparatus.

11. A material processing method comprising treating a material substrate with an output beam of a pulsed laser characterized by a pulse energy from about 1 nJ to about 2 mJ, a pulse time from about 50 ps to about 500 ns and a photon energy less than a bandgap energy of a material that comprises the material substrate, to provide a processed material substrate.

12. The method of claim 11 wherein the pulsed laser comprises a thulium fiber laser.

13. The method of claim 11 wherein the material substrate comprises a substrate material selected from the group consisting of a conductor substrate material, a semiconductor substrate material and a dielectric substrate material.

14. The method of claim 11 wherein the processed material substrate is processed within only a top surface of the processed material substrate.

15. The method of claim 11 wherein the processed material substrate is processed within only a bottom surface of the processed material substrate without damaging a top surface of the processed material substrate.

16. The method of claim 11 wherein the processed material substrate is processed within both a top surface of the processed material substrate and a bottom surface of the processed material substrate.

17. The method of claim 11 wherein a crater aperture is etched into a top surface of the processed material substrate.

18. The method of claim 11 wherein a trench aperture is etched into a top surface of the processed material substrate.

19. The method of claim 11 wherein a trench aperture is etched into a bottom surface of the processed material substrate with the pulsed laser beam incident upon a top surface of the processed material substrate and without damaging the top surface of the processed material substrate.

20. The method of claim 11 wherein the method is used in an application selected from the group consisting of materials substrate dicing applications, materials substrate metallization removal applications; materials substrate surface alloying applications, materials substrate layer connection applications and materials substrate layer disconnection applications.

21. A material processing method comprising irradiating a front side of a semiconductor substrate with an output beam of a thulium fiber pulsed laser characterized by a pulse energy from about 1 nJ to about 2 mJ, a pulse time from about 50 ps to about 500 ns and a photon energy less than a bandgap energy of a semiconductor material that comprises the semiconductor substrate, to provide a processed semiconductor substrate processed on a backside of the processed semiconductor substrate while not damaging the front side of the processed semiconductor substrate.

22. The method of claim 21 further comprising laterally moving the pulsed laser beam with respect to the semiconductor substrate when treating the semiconductor substrate with the pulsed laser beam.

23. The method of claim 21 wherein the processed semiconductor substrate includes an aperture within at least one of a front surface and a back surface of the processed semiconductor substrate, the aperture being selected from the group consisting of a crater aperture and a trench aperture.
